(19) United States
(12) Patent Application Publication
(10) Pub. No.: US 2014/0168887 A1
(43) Pub. Date: Jun. 19, 2014

(54) BAFFLE CONTROL DEVICE AND SERVER RACK USING SAME

(71) Applicant: HON HAI PRECISION INDUSTRY CO., LTD., New Taipei (TW)

(72) Inventors: CHIEN-PAN LAI, New Taipei (TW); CHIH-YUAN HUANG, New Taipei (TW)

(73) Assignee: HON HAI PRECISION INDUSTRY CO., LTD., New Taipei (TW)

(21) Appl. No.: 14/093,024

(22) Filed: Nov. 28, 2013

(30) Foreign Application Priority Data
Dec. 17, 2012 (TW) 101147702

(51) Int. Cl. H05K 7/20

(52) U.S. Cl. CPC H05K 7/20754; H05K 7/20209
USPC 361/679.46; 165/200

(57) ABSTRACT

A server rack includes a baffle control device and a plurality of server cases. Each server case accommodates a server and comprises an air inlet and a baffle located at a side of the air inlet to open or close the air inlet. The baffle control device includes a server monitoring unit and a baffle control unit. The server monitoring unit monitors a power on event and a power off event of the server. When the power on event of the server of a corresponding server case is monitored, the baffle control unit controls the baffle of the corresponding server case to open the air inlet of the corresponding server case. When the power off event of the server of the corresponding server case is monitored, the baffle control unit controls the baffle of the corresponding server case to close the air inlet of the corresponding server case.

### BACKGROUND

1. Technical Field

Embodiments of the present disclosure relate to cooling technologies used in a data center having a plurality of servers, and more particularly to a baffle control device and a server rack using the baffle control device.

2. Description of Related Art

A data center may include a plurality of servers to store large amounts of data. In order to manage the plurality of servers, a server rack is used to accommodate the servers. The server rack includes a plurality of server cases accommodating the servers. In order to cool the servers located in the server rack, each server case has a baffle at an opening of the server case. When a server is put into the server case, the baffle is always opened to allow a flow of cool air from a computer room air conditioning (CRAC) into the server case to cool the server. Then, the warm air within the server case may flow out of the server case from a side opposite to the baffle. However, if the server in the server case is not working, the cool air still flows into the server case and then out of the server case without being used, which may waste of energy of the CRAC. Therefore, there is room for improvement in the art.

### BRIEF DESCRIPTION OF THE DRAWINGS

FIG. 1 is a schematic view of a server rack according to an exemplary embodiment.

FIG. 2 illustrates a schematic diagram of a baffle control device of FIG. 1 connected to a plurality of servers and a plurality baffles.

FIG. 3 shows a schematic diagram of a plurality of driving units connected to the plurality of baffles of FIG. 2 according to one embodiment.

FIG. 4 shows a schematic diagram of the plurality of driving units installed within server cases of the server rack of FIG. 2 according to another embodiment.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”. The reference “a plurality of” means “at least two”.

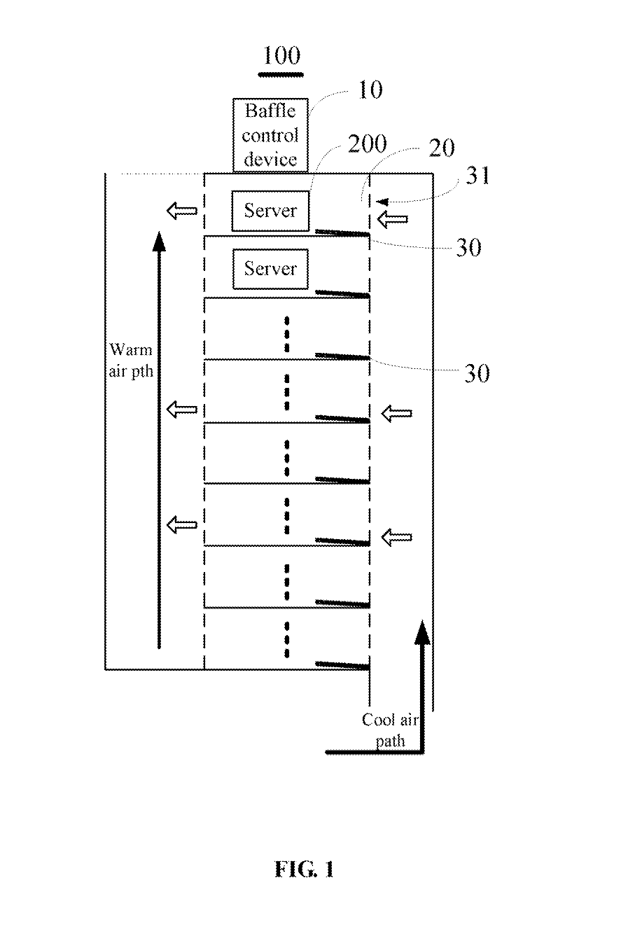

FIG. 1 shows a schematic view of a server rack 100 according to an exemplary embodiment. The server rack 100 includes a baffle control device 10 and a plurality of server cases 20. Each of the server cases 20 accommodates a server 200. In this embodiment, each server case 20 includes an air inlet 31 and a corresponding baffle 30 located at a side of the air inlet 31 to open or close the air inlet 31. Cool air provided by a computer room air conditioning (CRAC) via a cool air path may flow into each server case 20 via the air inlet 31 to cool the server 200 within each server case 20. Warm air within each server case 20 may flow out of the each server case 20 from a side opposite to the air inlet 31 and be exhausted out of the computer room (not shown) via a warm air path.

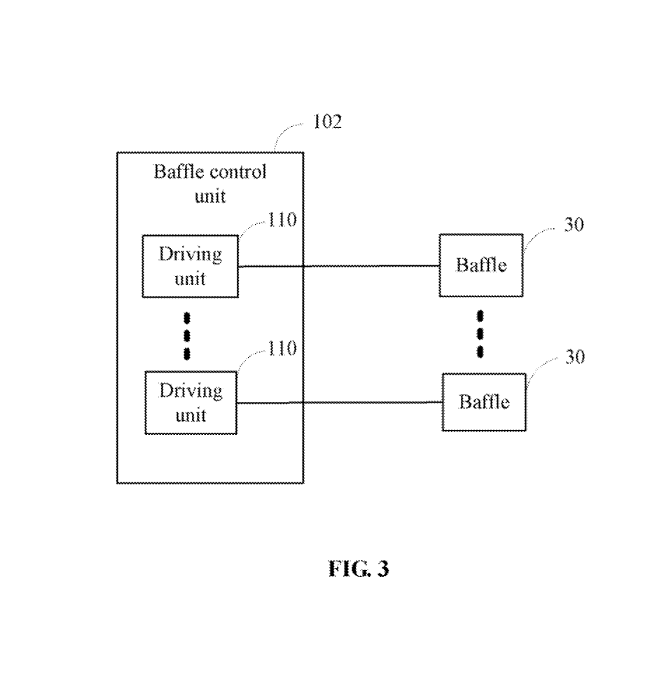

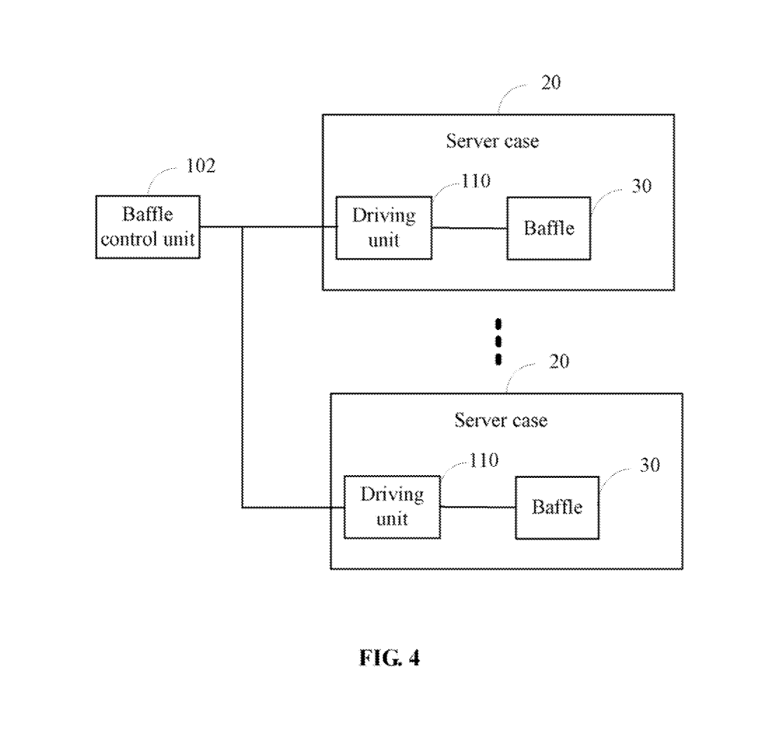

The baffle 30 of each server case 20 may be a shutter and be controlled by the baffle control device 100 to open or close the air inlet 31 of a corresponding server case 20. FIG. 3 and FIG. 4 show that in one embodiment, the baffle 30 of each server case 20 is connected to a driving unit 110 (e.g., a servo motor). The driving unit 110 can drive the baffle 30 to rotate along a first direction towards an inner space of the corresponding server case 20 to open the air inlet 31 of the corresponding server case 20, or drive the baffle 30 to rotate along a second direction opposite to the first direction to close the air inlet 31 of the corresponding server case 20.

In this embodiment, when the server 200 in the corresponding server case 20 is powered on, the baffle 30 of corresponding server case 20 is driven to open the air inlet 31 of the corresponding server case 20, to make the cool air to flow into the corresponding server case 20 and cool the server 200. When the server 200 in the corresponding server case 20 is powered off, the baffle 30 of corresponding server case 20 is driven to close the air inlet 31 of the corresponding server case 20, to prevent the cool air from flowing into the corresponding server case 20.

In other embodiments, the driving unit 110 may drives the baffle 30 to rotate with an appropriate degree according to working parameters (e.g., temperature and load) of the server 200. Thus, an amount of cool air flowing into the server case 20 can be controlled according to the working parameters of the server 200, to effectively use the cool air.

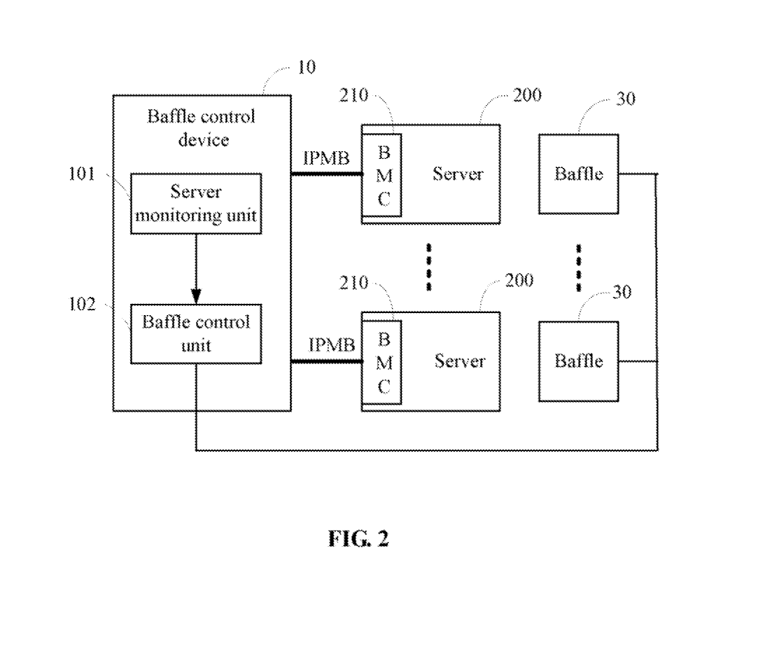

FIG. 2 shows that the baffle control device 10 is connected to the baffle 30 of each server case 20 and is connected to the server 200 accommodated within each server case 20. The baffle control device 10 includes a server monitoring unit 101 and a baffle control unit 102. The server 200 includes a baseboard management controller (BMC) 210. The baffle control device 10 is connected to the BMC 210 of the server 200 via an intelligent platform management bus (IPMB).

The server monitoring unit 101 monitors a power on event and a power off event of the server 200 of each server case 20 via the BMC 210 of the server 200. In this embodiment, when the server 200 is powered on or powered off, the BMC 210 of the server 200 sends an event log to the server monitoring unit 101 via the IPMB. The event log includes the power on event or the power off event of the server 200 and basic information (e.g., bus address, IP address, and MAC address) of the server 200. The BMC 210 can send the event log to the server monitoring unit 101 according to intelligent platform management interface (IPMI) protocol.

The baffle control unit 102 is connected to the baffle 30 of each server case 20. When the power on event of the server 200 of the corresponding server case 20 is monitored, the baffle control unit 101 controls the baffle 30 of the corresponding server case 20 to open the air inlet 31 of the corresponding server case 20, to allow the cool air to flow into the corresponding server case 20 and cool the server 200. When the power off event of the server 200 of the corresponding server case 20 is monitored, the baffle control unit 101 controls the baffle 30 of the corresponding server case 20 to close the air inlet 31 of the corresponding server case 20, to prevent the cool air from flowing into the corresponding server case 20.

The baffle control unit 102 analyzes the event log to determine whether the power on event of the power off event is monitored, and determine the corresponding server case 20 according to the basic information of server 200 recorded in the event log. Then, the baffle control unit 102 controls the baffle 30 of the corresponding server case 20 to open or close the air inlet 31 of the corresponding server case 20.

FIG. 3 shows that in one embodiment, the baffle control unit 102 includes a plurality of driving units 110. Each driving unit 110 is connected to the baffle 30 of one of the server cases 20, to drive the baffle 30 to open or close the air inlet 31 of the one of the server cases 20.

FIG. 4 shows that in another embodiment, each server case 20 includes a driving unit 110 connected to the baffle control unit 102 and the baffle 30 of the server case 20. The baffle control unit 102 can send a control command (e.g., “0001” representing the power on event or “0000” representing power off event) to the driving unit 110 of the corresponding server case 20. The driving unit 110 performs the control command to drive the baffle 30 of the corresponding server case 20 to open or close the air inlet 31 of the corresponding server case 20.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A baffle control device for a server rack having a plurality of server cases, each server case accommodating a server and comprising an air inlet and a baffle located at a side of the air inlet to open or close the air inlet, the baffle control device comprising:
a server monitoring unit connected to the server of each of the server cases, the server monitoring unit monitoring a power on event and a power off event of the server; and
a baffle control unit connected to the baffle of each of the server cases, the baffle control unit controlling the baffle of a corresponding server case to open the air inlet of the corresponding server case when the power on event of the server of the corresponding server case is monitored, and controlling the baffle of the corresponding server case to close the air inlet of the corresponding server case when the power off event of the server of the corresponding server case is monitored.

2. The baffle control device according to claim 1, wherein the server of each server case comprises a baseboard management controller (BMC), and the server monitoring unit monitors the power on event and the power off event via the BMC.

3. The baffle control device according to claim 2, wherein the baffle control unit is connected to the BMC of the server via an intelligent platform management bus (IPMB).

4. The baffle control device according to claim 3, wherein when the server is powered on or powered off, the BMC of the server sends an event log to the server monitoring unit via the IPMB.

5. The baffle control device according to claim 4, wherein the event log includes the power on event or the power off event of the server and basic information of the server.

6. The baffle control device according to claim 1, wherein the baffle control unit comprises a plurality of driving units and each of the driving units is connected to the baffle of one of the server cases, to drive the baffle to open or close the air inlet of the one of the server cases.

7. The baffle control device according to claim 1, wherein each server case comprises a driving unit connected to the baffle control unit and the baffle of the server case, the baffle control unit sends a control command according to the power on event or the power off event to the driving unit of the corresponding server case, and the driving unit drives the baffle of the corresponding server case to open or close the air inlet of the corresponding server case according to the control command.

8. A server rack, comprising:
a plurality of server cases, each server case accommodating a server and comprising an air inlet and a baffle located at a side of the air inlet to open or close the air inlet; and
a baffle control device comprising:
a server monitoring unit connected to the server of each of the server cases, the server monitoring unit monitoring a power on event and a power off event of the server; and
a baffle control unit connected to the baffle of each of the server cases, the baffle control unit controlling the baffle of a corresponding server case to open the air inlet of the corresponding server case when the power on event of the server of the corresponding server case is monitored, and controlling the baffle of the corresponding server case to close the air inlet of the corresponding server case when the power off event of the server of the corresponding server case is monitored.

9. The server rack according to claim 1, wherein the server of each server case comprises a baseboard management controller (BMC), and the server monitoring unit monitors the power on event and the power off event via the BMC.

10. The server rack according to claim 9, wherein the baffle control unit is connected to the BMC of the server via an intelligent platform management bus (IPMB).

11. The server rack according to claim 10, wherein when the server is powered on or powered off, the BMC of the server sends an event log to the server monitoring unit via the IPMB.

12. The server rack according to claim 11, wherein the event log includes the power on event or the power off event of the server and basic information of the server.

13. The server rack according to claim 8, wherein the baffle control unit comprises a plurality of driving units and each of the driving units is connected to the baffle of one of the server cases, to drive the baffle to open or close the air inlet of the one of the server cases.

14. The server rack according to claim 8, wherein each server case comprises a driving unit connected to the baffle control unit and the baffle of the server case, the baffle control unit sends a control command according to the power on event or the power off event to the driving unit of the corresponding server case, and the driving unit drives the baffle of the corresponding server case to open or close the air inlet of the corresponding server case according to the control command.
